(19) United States
(12) Patent Application Publication
(10) Pub. No.: US 2022/0003864 A1
(43) Pub. Date: Jan. 6, 2022

(54) DISTANCE MEASURING METHOD, DISTANCE MEASURING DEVICE, AND RECORDING MEDIUM

(71) Applicant: Panasonic Intellectual Property Management Co., Ltd., Osaka (JP)

(72) Inventors: Yugo Nose, Kyoto (JP); Shinzo KOYAMA, Osaka (JP); Akihiro ODAGAWA, Osaka (JP); Shigetaka KASUGA, Osaka (JP); Manabu USUDA, Hyogo (JP)

(21) Appl. No.: 17/481,233

(22) Filed: Sep. 21, 2021

Related U.S. Application Data
(63) Continuation of application No. PCT/JP2020/012287, filed on Mar. 19, 2020.

(30) Foreign Application Priority Data
Mar. 27, 2019 (JP) 2019-061965

(51) Int. Cl. G01S 17/08; H01L 31/107; G01S 7/48

(52) U.S. Cl. CPC G01S 17/08; G01S 7/4865; G01S 7/4808; H01L 31/107

(57) ABSTRACT

A distance measuring method according to the present disclosure includes: measuring, in an environment where background light is applied to an object, the illuminance of the background light; setting a distance measuring range based on the illuminance of the background light; setting, based on the distance measuring range set, an image capturing condition for an image capturer including a plurality of pixels each including an avalanche photo diode (APD) and an emission condition in which light is emitted from a light source; and measuring a distance to the object by controlling the image capturer and the light source based on the image capturing condition and the emission condition that are set.

### CROSS REFERENCE TO RELATED APPLICATIONS

This is a continuation application of PCT International Application No. PCT/JP2020/012287 filed on Mar. 19, 2020, designating the United States of America, which is based on and claims priority of Japanese Patent Application No. 2019-061965 filed on Mar. 27, 2019. The entire disclosures of the above-identified applications, including the specifications, drawings and claims are incorporated herein by reference in their entirety.

### FIELD The present disclosure relates to distance measuring methods, distance measuring devices, and recording media.

### BACKGROUND

Conventionally, there is a distance measuring device that uses light such as near-infrared light to measure a distance to an object serving as a target (see, for example, PTL 1).

A radar device that is a distance measuring device disclosed in PTL 1 includes: a laser diode which applies light to an object serving as a target; first and second light receiving circuits on which reflected light resulting from reflection of the applied light off the object is incident and which convert the incident reflected light into signals; and a central processing unit (CPU). The CPU generates, from the two signals output from the two light receiving circuits, a combined signal in which an active region serving as a range of light intensity values capable of being output in signals proportional to the light intensity values of the incident reflected light is extended as compared with the original two signals.

In this way, in the conventional distance measuring device, even with reflected light in a wide dynamic range, an accurate distance can be measured. In the conventional distance measuring device, in one of the two light receiving circuits, an avalanche photo diode (APD) is used. The APD is a photodiode that uses avalanche breakdown to multiply charge generated by photoelectric conversion of light incident on a photoelectric conversion layer (that is, avalanche multiplication) so as to increase light detection sensitivity. In the APD, even when reflected light of low brightness is incident, a signal proportional to the intensity of the reflected light can be output from the light receiving circuit.

### CITATION LIST

### Patent Literature

PTL 1: Japanese Unexamined Patent Application Publication No. 2008-20203

### SUMMARY

### Technical Problem

Incidentally, there is conventionally a technique for correcting the intensity of light incident on a light receiving circuit by use of background light which is external light such as sunlight in order to accurately detect reflected light. Here, for example, when the background light is sunlight, the intensity of the background light is different depending on time, weather, or the like. When the intensity of the background light is different, a difference between the intensity of the reflected light and the intensity of the background light is excessively reduced, with the result that the reflected light cannot be detected depending on conditions. Disadvantageously, the conventional distance measuring device calculates, depending on the intensity of the background light, a distance that cannot be measured.

The present disclosure provides a distance measuring method by which it is possible to appropriately measure a distance and the like.

### Solution to Problem

A distance measuring method according to an aspect of the present disclosure includes: measuring, in an environment where background light is applied to an object, an illuminance of the background light; setting a distance measuring range based on the illuminance of the background light; setting, based on the distance measuring range set, an image capturing condition for an image capturer including a plurality of pixels each including an avalanche photo diode (APD) and an emission condition in which light is emitted from a light source; and measuring a distance to the object by controlling the image capturer and the light source based on the image capturing condition and the emission condition that are set.

A distance measuring device according to an aspect of the present disclosure includes: a light measurer that measures, in an environment where background light is applied to an object, an illuminance of the background light; a calculator that sets a distance measuring range based on the illuminance of the background light; and a controller that sets, based on the distance measuring range set, an image capturing condition for an image capturer including a plurality of pixels each including an avalanche photo diode (APD) and an emission condition in which light is emitted from a light source and that controls the image capturer and the light source based on the image capturing condition and the emission condition which are set so as to measure a distance to the object.

The present disclosure may be realized as programs that instruct a computer to execute the steps included in the distance measuring method. The present disclosure may also be realized as a non-transitory computer-readable recording medium, such as a CD-ROM, in which the programs are recorded. The present disclosure may also be realized as information, data, or signals indicating the programs. The programs, the information, the data, and the signals may be distributed through a communication network such as the Internet.

### Advantageous Effects

According to the present disclosure, it is possible to provide a distance measuring device that can appropriately measure a distance and the like.

### BRIEF DESCRIPTION OF DRAWINGS

These and other advantages and features Will become apparent from the following description thereof taken in conjunction with the accompanying Drawings, by way of non-limiting examples of embodiments disclosed herein.

FIG. 1 is a diagram for illustrating an outline of a distance measuring device according to Embodiment 1.

FIG. 2 is a diagram for illustrating a distance measuring method performed by the distance measuring device according to Embodiment 1.

FIG. 3 is a block diagram showing a characteristic functional configuration of the distance measuring device according to Embodiment 1.

FIG. 4 is a flowchart for illustrating the distance measuring method performed by the distance measuring device according to Embodiment 1.

FIG. 5 is a diagram for illustrating a method for calculating, by the distance measuring device according to Embodiment 1, a limit distance measuring range from the occurrence count of avalanche multiplication.

FIG. 6 is a flowchart for illustrating an example of a method for selecting, by the distance measuring device according to Embodiment 1, table information used when the limit distance measuring range is calculated.

FIG. 7 is a diagram for illustrating the example of the method for selecting, by the distance measuring device according to Embodiment 1, the table information used when the limit distance measuring range is calculated.

FIG. 8 is a diagram showing an example of the occurrence count of avalanche multiplication in each of a plurality of APDs acquired when the distance measuring device according to Embodiment 1 measures a distance to an object.

FIG. 9 is a diagram for illustrating a specific example of a method for calculating an illuminance performed by the distance measuring device according to Embodiment 1.

FIG. 10 is a block diagram showing a characteristic functional configuration of a distance measuring device according to Embodiment 2.

FIG. 11 is a flowchart for illustrating a distance measuring method performed by the distance measuring device according to Embodiment 2.

FIG. 12 is a flowchart for illustrating details of a light measuring method performed by the distance measuring device according to Embodiment 2.

FIG. 13 is a flowchart for illustrating details of processing for setting a distance measuring range performed by the distance measuring device according to Embodiment 2.

FIG. 14 is a flowchart for illustrating details of processing for setting image capturing conditions and emission conditions performed by the distance measuring device according to Embodiment 2.

### DESCRIPTION OF EMBODIMENTS

Embodiments of the present disclosure will be described below with reference to drawings. The embodiments described below indicate preferred specific examples of the present disclosure. Hence, values, constituent elements, the arrangement positions and connection forms of the constituent elements, steps, the order of the steps, and the like described in the following embodiments are examples and are not intended to limit the present disclosure.

The drawings are schematic views and are not exactly shown. Hence, scales and the like are not necessarily the same in the drawings. In the drawings, substantially the same configurations are identified with the same signs, and repeated descriptions may be omitted or simplified.

### EMBODIMENT 1

### [Configuration]

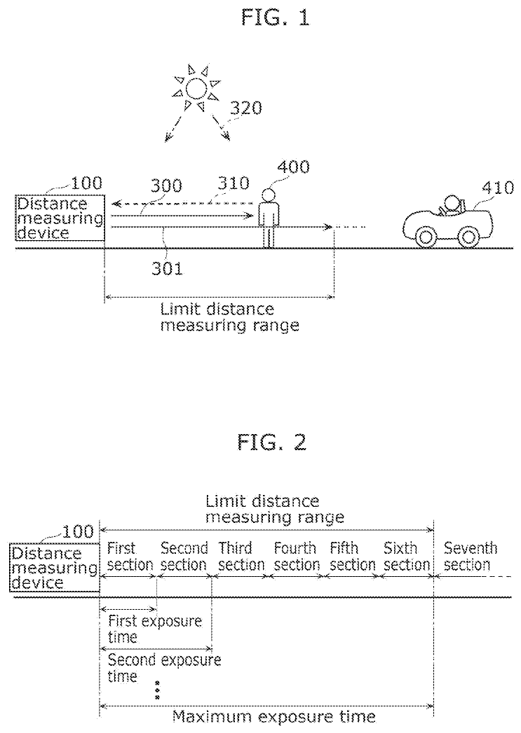

The configuration of a distance measuring device according to Embodiment 1 will first be described with reference to FIGS. 1 to 3.

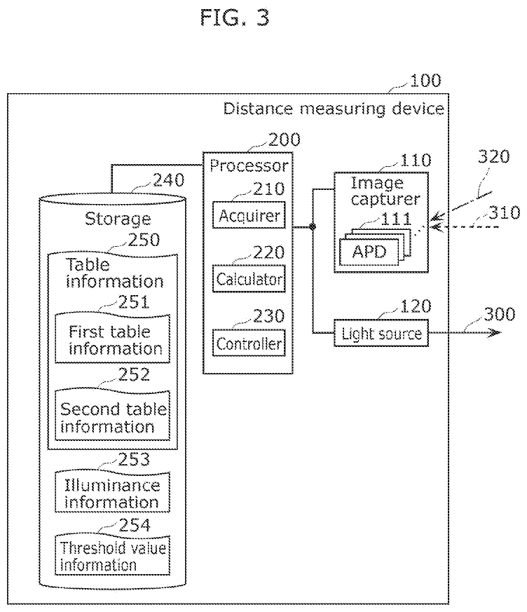

FIG. 1 is a diagram for illustrating an outline of distance measuring device 100 according to Embodiment 1. FIG. 2 is a diagram for illustrating a distance measuring method performed by distance measuring device 100 according to Embodiment 1. FIG. 3 is a block diagram showing a characteristic functional configuration of distance measuring device 100 according to Embodiment 1.

Distance measuring device 100 is a device that measures a distance to an object, Specifically, distance measuring device 100 emits emission light 300 toward the object, image capturer 110 that includes a plurality of avalanche photo diodes (APD) 111 detects reflected light 310 that is light resulting from reflection of emission light 300 off the object, and thus the distance between distance measuring device 100 and the object is measured. More specifically, distance measuring device 100 calculates the distance to the object by a time of flight (TOF) method.

The TOF method is a method of calculating the distance from a time that elapses after light source 120 is caused to emit emission light 300 until emission light 300 emitted by light source 120 hits the object and then reflected light 310 which is light resulting from reflection of emission light 300 off the objects detected. Distance measuring device 100 emits emission light 300 toward, for example, target 400 such as a person. Emission light 300 is reflected off target 400 to be reflected light 310. Reflected light 310 is incident on distance measuring device 100. Distance measuring device 100 measures a distance to target 400 based on a time that elapses after emission light 300 is emitted until reflected light 310 is detected.

As shown in FIG. 2, for example, distance measuring device 100 exposes image capturer 110 for a predetermined exposure time (first exposure time), and counts, in the meantime, the number of times avalanche multiplication occurs (occurrence count of avalanche multiplication) in each of APDs 111. For example, when the occurrence count of avalanche multiplication that is counted is greater than or equal to a predetermined occurrence count that is previously arbitrarily determined, distance measuring device 100 determines that an object exists in a first section whereas when the occurrence count of avalanche multiplication is less than the predetermined occurrence count, distance measuring device 100 determines that an object does not exist in the first section.

When distance measuring device 100 determines that an object does not exist in the first section, distance measuring device 100 further exposes image capturer 110 for a predetermined exposure time (second exposure time) longer than the first exposure time, and counts, in the meantime, the occurrence count of avalanche multiplication in each of APDs 111. For example, when the occurrence count of avalanche multiplication that is counted is greater than or equal to a predetermined occurrence count, distance measuring device 100 determines that an object exists in a second section whereas when the occurrence count of avalanche multiplication is less than the predetermined occurrence count, distance measuring device 100 determines that an object does not exist in the second section. Distance measuring device 100 repeats processing as described above to determine in which section an object is located, that is, to measure, when an object exists, a distance to the object.

Here, for example, in distance measuring device 100, a limit distance measuring range is set that is a limit of a distance which can be measured in distance measuring device 100 (specifically, image capturer 110). When target 410 exists in a position more distant from distance measuring device 100 than the limit distance measuring range, distance measuring device 100 cannot measure a distance to the object, for example, because light emitted from light source 120 does not reach the object. For example, when in FIG. 2, an object is located from the first section to a sixth section, distance measuring device 100 can measure in which section the object exists. On the other hand, when an object exists in a seventh section, distance measuring device 100 cannot determine whether or not the object exists, and naturally cannot measure a distance to the object.

Specifically, for example, as shown in FIG. 1, distance measuring device 100 is assumed to emit emission light 300 toward target 400. In this case, since target 400 exists in a position closer from distance measuring device 100 than the limit distance measuring range, distance measuring device 100 detects, for example, reflected light 310 to measure a distance to target 400.

On the other hand, distance measuring device 100 is assumed to emit emission light 301 toward target 410 such as a vehicle that exists in a position more distant than target 400. In this case, when target 410 exists in a position more distant from distance measuring device 100 than the limit distance measuring range, for example, emission light 301 does not reach target 410, and thus distance measuring device 100 cannot detect reflected light, with the result that distance measuring device 100 cannot measure a distance to target 410.

As described above, there is a limit for a distance that can be measured with distance measuring device 100. Hence, in the convention& distance measuring device, the limit distance measuring range is previously determined. In other words, the maximum time (maximum exposure time) which is calculated based on the limit distance measuring range and for which image capturer 110 is exposed is previously determined. For example, as the limit distance measuring range is shorter, the maximum exposure time is shorter. On the other hand, as the limit distance measuring range is longer, the maximum exposure time is longer.

However, depending on the illuminance of background light 320, such as sunlight, that is not emission light 300 emitted from light source 120, the limit distance measuring range is changed. For example, when the illuminance of background light 320 is very high, the illuminance of reflected light 310 is significantly lowered relative to the illuminance of background light 320, and thus reflected light 310 cannot be detected with image capturer 110. In other words, in this case, the limit distance measuring range that can be actually measured is shorter than the limit distance measuring range that is previously determined. Hence, in the conventional distance measuring device, depending on the illuminance of background light 320, the limit distance measuring range is previously determined for a distance that cannot be measured, with the result that processing for calculating the distance is performed. In distance measuring device 100 according to the present disclosure, the limit distance measuring range is calculated such that, for a distance to an object which cannot be measured because the illuminance of background light 320 is excessively high and thus a large amount of noise is detected, the distance is prevented from being calculated, with the result that calculation for measuring an appropriate distance is performed.

As shown in FIG. 3, distance measuring device 100 includes image capturer 110, light source 120, processor 200, and storage 240.

Image capturer 110 is a camera that includes a plurality of APDs 111. APD 111 is a photodiode that performs avalanche multiplication on charge generated by photoelectric conversion of light incident on a photoelectric conversion layer so as to increase light detection sensitivity. Image capturer 110 includes, for example, a plurality of APDs 111 arranged in a matrix,

As long as a plurality of APDs 111 are included in image capturer 110, the number of APDs 111 is not particularly limited.

Light source 120 is a light source that emits emission light 300. Light source 120 is, for example, a light emitting diode (LED), a laser diode (LD), or the like. The wavelength of the light emitted by light source 120 is not particularly limited. Light source 120 emits, for example, near-infrared light whose center wavelength is about 800 to 1200 nm.

Processor 200 is a processor that controls image capturer 110 and light source 120 to measure a distance to an object (for example, target 400).

Processor 200 is realized, for example, by a central processing unit (CPU) and a control program that is stored in storage 240 or the like and that is executed by the CPU. Processor 200 is connected to image capturer 110 and light source 120 with control lines or the like to be able to communicate therewith.

Processor 200 functionally includes acquirer 210, calculator 220, and controller 230.

Acquirer 210 is connected to image capturer 110 to acquire information of reflected light 310 detected in image capturer 110. Specifically, acquirer 210 acquires, from image capturer 110, in an environment where background light 320 is applied to the object, the occurrence count of avalanche multiplication in each of a plurality of APDs 111 included in image capturer 110. Acquirer 210 may acquire, from image capturer 110, the occurrence count of avalanche multiplication in each of APDs 111 or information indicating that avalanche multiplication occurs. When acquirer 210 acquires the information indicating that avalanche multiplication occurs, for example, acquirer 210 counts the number of times the information is acquired to acquire the occurrence count of avalanche multiplication in each of APDs 111.

Based on the occurrence count of avalanche multiplication in each of APDs 111 that is acquired by acquirer 210, calculator 220 calculates the limit distance measuring range indicating a distance that can be measured with image capturer 110. Specifically, calculator 220 calculates the limit distance measuring range in an environment where light source 120 does not emit emission light 300 and where background light 320 is applied based on the occurrence count of avalanche multiplication in each of APDs 111 that is acquired by acquirer 210.

For example, calculator 220 calculates the illuminance of background light 320 based on the occurrence count of avalanche multiplication in each of APDs 111, and calculates the limit distance measuring range based on the calculated illuminance of background light 320. For example, calculator 220 calculates the illuminance of background light 320 from the occurrence count of avalanche multiplication based on illuminance information 253.

Illuminance information 253 is a table that indicates a correlation between the occurrence count of avalanche multiplication and the illuminance. Illuminance information 253 is stored, for example, in storage 240. Calculator 220 calculates the illuminance of background light 320 from the occurrence count of avalanche multiplication in each of APDs 111 that is acquired by acquirer 210 in the environment where light source 120 does not emit emission light 300 and where background light 320 is applied and illuminance information 253. Then, calculator 220 calculates the limit distance measuring range based on the calculated illuminance.

For example, calculator 220 calculates the illuminance of background light 320 based on the average value of the occurrence counts of avalanche multiplication in at least two or more of APDs 111.

Alternatively, calculator 220 calculates the illuminance of background light 320 based on the average value of the occurrence counts of avalanche multiplication in all of APDs 111.

For example, calculator 220 calculates the limit distance measuring range based on the calculated illuminance of background light 320 and table information 250.

Table information 250 is a table that indicates a correlation (that is, the limit distance measuring range for the illuminance) between the illuminance and the limit distance measuring range. Table information 250 is stored, for example, in storage 240.

Table information 250 includes, for example, first table information 251 and second table information 252 that is different from first table information 251 in regard to the correlation between the illuminance and the limit distance measuring range. For example, calculator 220 calculates an S/N ratio that is a ratio (specifically, a ratio of the magnitude of the illuminance) of the illuminance of light resulting from reflection of the light emitted from light source 120 off the object to the illuminance of background light 320 from the occurrence count of avalanche multiplication in each of APDs 111 when controller 230 causes light source 120 to emit the light and the occurrence count of avalanche multiplication in each of APDs 111 when controller 230 does not cause light source 120 to emit the light. Based on the calculated Sill ratio, calculator 220 further selects whether to calculate the limit distance measuring range based on first table information 251 or to calculate the limit distance measuring range based on second table information 252.

For example, calculator 220 calculates the illuminance of background light 320 and a difference between the illuminance of reflected light 310 and the illuminance of background light 320. Then, calculator 220 calculates a ratio of the calculated difference to the illuminance of background light 320 to calculate the S/N ratio.

For example, at each illuminance between a first threshold value indicating an illuminance and a second threshold value indicating an illuminance higher than the illuminance of the first threshold value, the limit distance measuring range corresponding to the illuminance in first table information 251 is longer than that in second table information 252. For example, when the illuminance of background light 320 drops below the first threshold value, calculator 220 determines the limit distance measuring range based on first table information 251 whereas when the illuminance of background light 320 exceeds the second threshold value, calculator 220 calculates the limit distance measuring range based on second table information 252.

Controller 230 controls the exposure of image capturer 110 and the emission of emission light 300 from light source 120. For example, by the TOF method, controller 230 exposes image capturer 110 and causes light source 120 to emit emission light 300 to calculate the distance to the object based on the occurrence count of avalanche multiplication in each of APDs 111.

For example, controller 230 calculates the maximum exposure time for which image capturer 110 is exposed based on the limit distance measuring range calculated by calculator 220, exposes image capturer 110 for an exposure time within the calculated maximum exposure time, and calculates the distance to the object based on the occurrence count of avalanche multiplication in each of APDs 111. More specifically, controller 230 calculates the maximum value (maximum exposure time) of the exposure time based on the limit distance measuring range. Controller 230 repeats, for the maximum exposure time based on the limit distance measuring range, processing for exposing image capturer 110 for a predetermined exposure time and further extending the exposure time for a predetermined time to expose image capturer 110 again.

Controller 230 may perform, a multiple number of times, for the measurement of one distance, exposure processing that is performed when the distance to the object is measured and that exposes image capturer 110. For example, in order to determine whether or not an object exists in the first section shown in FIG. 2, controller 230 may expose image capturer 110 for the same exposure time a multiple number of times. For example, calculator 220 may determine whether or not an object exists in the first section, that is, measure (calculate) the distance to the object from the average value of the occurrence counts of avalanche multiplication acquired each time the exposure processing is performed.

A conversion method by which controller 230 calculates the maximum exposure time based on the limit distance measuring range may be set such that as the limit distance measuring range is shorter, the maximum exposure time is shorter, and the conversion method is not particularly limited. For example, the conversion method may be stored in storage 240 as a table indicating the maximum exposure time for the limit distance measuring range or a conversion formula for calculating the maximum exposure time from the limit distance measuring range may be stored in storage 240.

For example, controller 230 selects a predetermined exposure time serving as an exposure time within the maximum exposure time from a plurality of predetermined exposure times that are different from each other, exposes image capturer 110 for the selected predetermined exposure time serving as the exposure time within the maximum exposure time, and calculates the distance to the object based on the occurrence count of avalanche multiplication in each of APDs 111 acquired for each predetermined exposure time serving as the exposure time within the maximum exposure time.

For example, as shown in FIG. 2, a plurality of predetermined exposure times (such as the first exposure time and the second exposure time) are stored in storage 240 such that when a distance is measured in the first section, controller 230 exposes image capturer 110 for the first exposure time and that when a distance is measured in the second section, controller 230 exposes image capturer 110 for the second exposure time. In other words, to the sections where distances are measured, different predetermined exposure times are previously allocated.

Based on the maximum exposure time, that is, based on the limit distance measuring range, controller 230 selects the predetermined exposure time serving as the exposure time within the maximum exposure time from a plurality of predetermined exposure times. For example, as shown in FIG. 2, the maximum exposure time is assumed to be greater than or equal to an exposure time (sixth exposure time) for which a distance in the sixth section is measured and less than an exposure time for which a distance in the seventh section is measured. In this case, controller 230 selects, from a plurality of predetermined exposure times that are previously determined, six predetermined exposure times from the first exposure time to the sixth exposure time. Furthermore, controller 230 exposes image capturer 110 for each of the selected predetermined exposure times serving as the exposure times within the maximum exposure time. For example, controller 230 repeatedly performs, while changing the exposure times, exposure processing until exposure processing for exposing image capturer 110 for the sixth exposure time such that exposure processing for exposing image capturer 110 for the first exposure time is performed and that exposure processing for exposing image capturer 110 for the second exposure time is further performed.

Controller 230 calculates the distance to the object based on the occurrence counts of avalanche multiplication in APDs 111 acquired each time the exposure processing is performed in the performance of the exposure processing a multiple number of times as described above. For example, while image capturer 110 is being exposed, controller 230 causes light source 120 to emit the light (emission light 300) for a predetermined number of times of emission.

The exposure times, the number of times of exposure for each of the exposure times, and the number of times of emission of the light from light source 120 may be arbitrarily determined.

Controller 230 may calculate, based on the maximum exposure time, the predetermined exposure times, the number of times of exposure, and the number of times of emission. For example, controller 230 repeatedly exposes image capturer 110 for the calculated number of times of exposure for each of the calculated predetermined exposure times, and causes light source 120 to emit the light for the calculated number of times of emission.

For example, controller 230 performs the exposure processing for the predetermined number of times of exposure for the same exposure time. The number of times of exposure may be previously arbitrarily determined, and the exposure may be performed once or a multiple number of times. The number of times of exposure may be stored, for example, in storage 240.

Here, for example, controller 230 may calculate, based on the maximum exposure time, the number of times the exposure processing is performed. For example, controller 230 may change, based on the maximum exposure time, the number of times of exposure stored in storage 240.

For example, controller 230 controls image capturer 110 so as not to substantially change the exposure time necessary for performing the entire distance measuring once (that is, the time necessary for performing distance measuring once). In this case, for example, when the maximum exposure time is up to the sixth section shown in FIG. 2, controller 230 exposes image capturer 110 once for each of the exposure times from the first exposure time to the sixth exposure time whereas when the maximum exposure time is up to the fourth section shown in FIG. 2, controller 230 exposes image capturer 110 twice for each of the exposure times from the first exposure time to the fourth exposure time.

As described above, controller 230 may change, based on the maximum exposure time, the number of times of exposure for each of the exposure times. For example, controller 230 reduces the number of times of exposure as the maximum exposure time is longer, and increases the number of times of exposure as the maximum exposure time is shorter, with the result that the time necessary for performing distance measuring once is substantially the same regardless of the maximum exposure time.

The distances of the sections within the limit distance measuring range do not need to be evenly divided. For example, when a measurement distance is 50 m and is divided into three sections, the sections may be divided such that the first section is 0 to 5 m, the second section is 5 to 15 m, and the third section is 15 to 50 m. In other words, the time for which controller 230 exposes image capturer 110 may be arbitrarily determined.

For example, controller 230 may increase the number of sections within the limit distance measuring range based on the limit distance measuring range (that is, increase the number of times of exposure for different exposure times) so as to change widths obtained by dividing the distance. In this way, it is possible to finely measure the distance, and thus the accuracy of distance measuring is enhanced.

For example, for each of the sections (that is, the exposure times), the number of times of emission of the light from light source 120 (when the light is laser, for example, the number of times of pulsing of the laser) may be different. In other words, the exposure times for the sections (exposure time when the light is emitted once×the number of times of emission) may be different.

For example, when the distance between distance measuring device 100 and the object is short, since reflected light 310 is easily detected, even if the number of times of emission is small, the distance is easily measured with a high degree of accuracy. On the other hand, for example, when the distance between distance measuring device 100 and the object is long, since reflected light 310 is unlikely to be detected, if the number of times of emission is small, the distance is unlikely to be measured with a high degree of accuracy. Hence, for example, controller 230 performs calculation such that as the distance from distance measuring device 100 is increased (that is, as the exposure time is increased), the number of times of emission is increased. In particular, since the accuracy of distance measuring (that is, the S/N ratio) is lowered in the section in the boundary of the limit distance measuring range, for example, controller 230 allocates an unnecessary time outside the limit distance measuring range so as to increase the number of times of emission (number of times of performance) in such a section. In other words, controller 230 increases the number of times of emission of the light from light source 120 as the exposure time is closer to the maximum exposure time. For example, controller 230 performs calculation such that the number of times of emission in the first section (0 to 5 m) is two, the number of times of emission in the second section (5 to 15 m) is five, and the number of times of emission in the third section (15 to 50 m) is ten.

In this way, the accuracy of distance measuring in the sections, in particular, in sections close to the limit distance measuring range is enhanced.

For example, controller 230 may cause image capturer 110 to perform, a multiple number of times, the exposure processing for calculating the limit distance measuring range by calculator 220. Specifically, for example, controller 230 causes image capturer 110 to perform the exposure processing for exposure a multiple number of times. In this case, for example, acquirer 210 acquires, for example, the occurrence counts of avalanche multiplication in APDs 111 each time the exposure processing is performed. For example, calculator 220 calculates the illuminance of background light 320 based on the average value of the occurrence counts of avalanche multiplication in APDs 111 acquired by acquirer 210 each time the exposure processing is performed.

Storage 240 is a storage device in which the control program executed by processor 200 and the like are stored. Storage 240 is realized, for example, by a hard disk drive (HDD), a flash memory or the like.

Storage 240 also stores, for example, table information 250 indicating the correlation between the illuminance and the limit distance measuring range that are previously determined. Specifically, for example, storage 240 stores, as table information 250, first table information 251 and second table information 252 that is different from first table information 251 in regard to the correlation between the illuminance and the distance measuring range.

Storage 240 also stores illuminance information 253 indicating the correlation between the occurrence count of avalanche multiplication and the illuminance.

Storage 240 also stores, for example, as threshold value information 254, the first threshold value indicating an illuminance and the second threshold value indicating an illuminance higher than the illuminance of the first threshold value.

### [Distance Measuring Method]

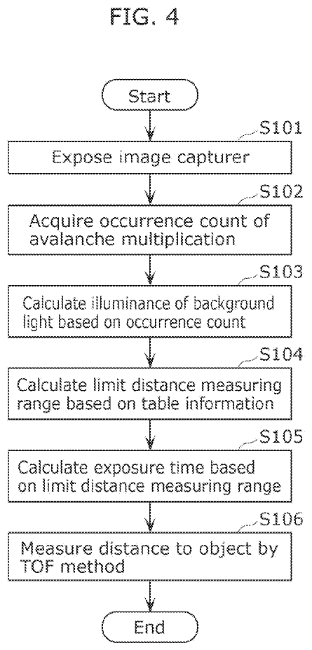

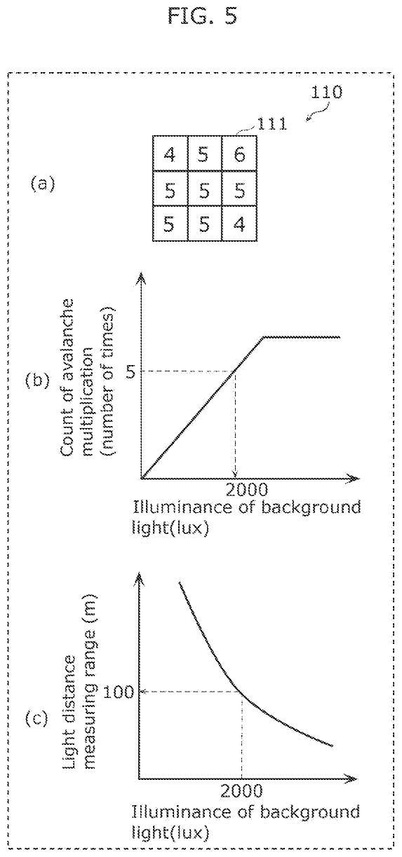

The distance measuring method performed by distance measuring device 100 will then be described with reference to FIGS. 4 to 9.

FIG. 4 is a flowchart for illustrating the distance measuring method performed by distance measuring device 100 according to Embodiment 1.

Controller 230 first controls image capturer 110 to expose image capturer 110 (step S101). A time for which controller 230 exposes image capturer 110 may be arbitrarily determined.

Then, acquirer 210 acquires, from image capturer 110, the occurrence count of avalanche multiplication in each of APDs 111 included in image capturer 110 (step S102).

Then, calculator 220 calculates the illuminance of background light 320 based on the occurrence count of avalanche multiplication acquired by acquirer 210 (step S103). In step S103, for example, calculator 220 calculates, based on illuminance information 253, the illuminance of background light 320 from the occurrence count of avalanche multiplication acquired by acquirer 210.

Then, calculator 220 calculates the limit distance measuring range based on table information 250 (step S104). In step S104, for example, calculator 220 calculates, based on table information 250, the limit distance measuring range from the calculated illuminance of background light 320.

FIG. 5 is a diagram for illustrating a method for calculating, by distance measuring device 100 according to Embodiment 1, the limit distance measuring range from the occurrence count of avalanche multiplication. Specifically, (a) in FIG. 5 is a diagram showing the occurrence count of avalanche multiplication in each of APDs 111 included in image capturer 110. (a) in FIG. 5 shows, as an example, the occurrence count of avalanche multiplication in each of nine APDs 111 when image capturer 110 includes nine APDs 111 arranged in a matrix of 3 rows and 3 columns. (b) in FIG. 5 is a diagram showing an example of illuminance information 253. (c) in FIG. 5 is a diagram showing an example of table information 250.

For example, acquirer 210 is assumed to acquire, from image capturer 110, the occurrence count of avalanche multiplication in each of nine APDs 111 as shown in (a) in FIG. 5.

In this case, calculator 220 calculates, for example, the average value of the occurrence counts of avalanche multiplication in nine APDs 111. Here, for example, calculator 220 discards digits to the right of the decimal point in the result of the calculation to calculate that the average value is 5. Naturally, the result of the calculation as it is may be used. Then, calculator 220 calculates, from illuminance information 253 shown in (b) in FIG. 5, that the illuminance of background light 320 is 2000 lux. Then, calculator 220 calculates, from table information 250 shown in (c) in FIG. 5, that the limit distance measuring range is 100 m.

As described above, in steps S103 and S104, calculator 220 calculates the limit distance measuring range based on the occurrence count of avalanche multiplication in each of APDs 111 acquired by acquirer 210.

Here, calculator 220 counts the occurrence counts of avalanche multiplication in all APDs 111 included in image capturer 110 to calculate the illuminance of background light 320 from the average value of the occurrence counts of avalanche multiplication in all APDs 111 included in image capturer 110. Calculator 220 may count the occurrence counts of avalanche multiplication in at least two or more of APDs 111 to calculate the illuminance of background light 320 from the average value of the occurrence counts of avalanche multiplication in at least two of more of APDs 111. For example, calculator 220 may count the occurrence counts of avalanche multiplication in five APDs 111 consisting of APD 111 located in the center and four APDs 111 located on the top, bottom, left, and right of APD 111 in the center in the plane of the figure among APDs 111 shown in (a) in FIG. 5 so as to calculate the illuminance of background light 320 from the average value of the occurrence counts of avalanche multiplication in five APDs 111 described above.

As a result of APDs 111 being repeatedly exposed by controller 230, acquirer 210 may acquire the occurrence counts of avalanche multiplication a multiple number of times to acquire, in step S102, the average value of the acquired occurrence counts of avalanche multiplication. For example, the occurrence count of avalanche multiplication in each of APDs 111 shown in (a) in FIG. 5 is the average value of the occurrence counts of avalanche multiplication acquired when each of APDs 111 is exposed ten times.

In the present embodiment, storage 240 stores, as table information 250, first table information 251 and second table information 252 that are different from each other in the correlation between the illuminance and the limit distance measuring range. Calculator 220 changes the table information to be used between first table information 251 and second table information 252.

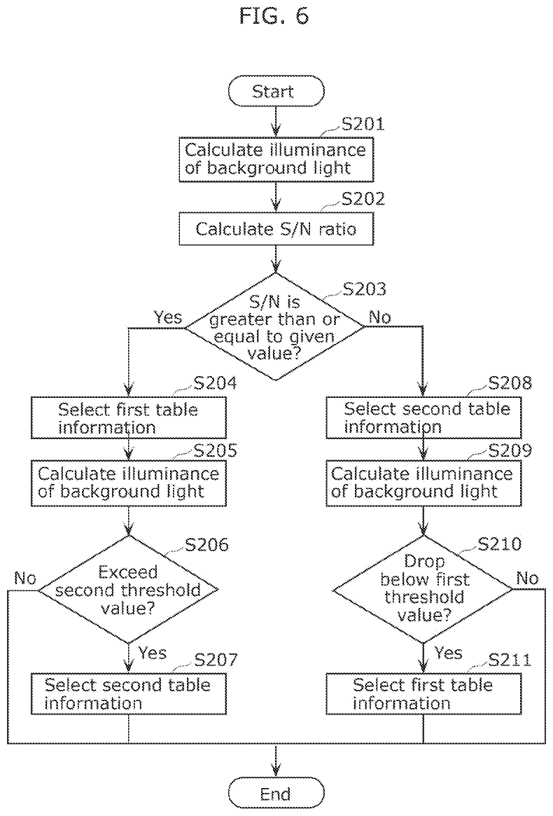

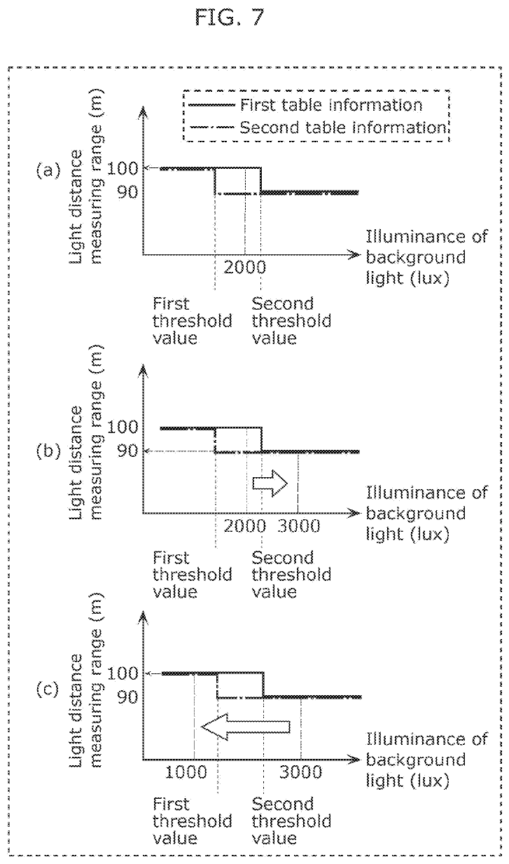

FIG. 6 is a flowchart for illustrating an example of a method for selecting, by distance measuring device 100 according to Embodiment 1, which one of first table information 251 and second table information 252 is used as the table when the limit distance measuring range is calculated. FIG. 7 is a diagram for illustrating the example of the method for selecting, by distance measuring device 100 according to Embodiment 1, which one of first table information 251 and second table information 252 is used as the table when the limit distance measuring range is calculated.

As shown in FIG. 6, calculator 220 first calculates the illuminance of background light 320 (step S201). In step S201, calculator 220 performs, for example, step S103 shown in FIG. 4.

Then, calculator 220 calculates an S/N ratio that is a ratio of the illuminance of light resulting from reflection of the light emitted from light source 120 off the object to the illuminance of background light 320 from the occurrence counts of avalanche multiplication in APDs 111 counted when controller 230 causes light source 120 to emit the light and the occurrence counts of avalanche multiplication in APDs 111 counted when controller 230 does not cause light source 120 to emit the light (step S202).

Then, calculator 220 determines whether or not the S/N ratio calculated in step S202 is greater than or equal to a given value that is previously determined (step S203).

When calculator 220 determines that the S/N ratio calculated in step S202 is greater than or equal to the given value that is previously determined (yes in step S203), calculator 220 selects first table information 251 (step S204). In this way, calculator 220 calculates the limit distance measuring range based on first table information 251.

On the other hand, when calculator 220 determines that the S/N ratio calculated in step S202 is not greater than or equal to the given value that is previously determined (no in step S203), calculator 220 selects second table information 252 (step S208). In this way, calculator 220 calculates the limit distance measuring range based on second table information 252.

As shown in (a) in FIG. 7, first table information 251 and second table information 252 are different in a method for conversion of the limit distance measuring range on the illuminance of background light 320. Specifically, first table information 251 is different from second table information 252 in regard to the conversion method between the previously determined first threshold value and the second threshold value indicating an illuminance higher than the illuminance of the first threshold value. More specifically, first table information 251 is a table in which calculator 220 performs conversion such that the limit distance measuring range in first table information 251 is longer than that in second table information 252 between the first threshold value and the second threshold value.

For example, calculator 220 is assumed to calculate, in step S202, that the illuminance of background light 320 is 2000 lux. In this case, as shown in (a) in FIG. 7, when calculator 220 determines that the S/N ratio is greater than or equal to the given value that is previously determined, calculator 220 calculates, based on first table information 251, that the limit distance measuring range is 100 m, On the other hand, when calculator 220 determines that the S/N ratio is not greater than or equal to the given value that is previously determined, calculator 220 calculates, based on second table information 252, that the limit distance measuring range is 90 m. As described above, when the S/N ratio is not high, calculator 220 calculates that the limit distance measuring range is low.

With reference back to FIG. 6, for example, calculator 220 calculates the illuminance of background light 320 again after a predetermined time has elapsed since the performance of step S204 (step S205). As described above, distance measuring device 100 may repeatedly calculate the illuminance of background light 320 for each predetermined time. In this way, even when background light 320 is changed depending on time, weather, or the like, calculator 220 can calculate an appropriate limit distance measuring range.

Then, calculator 220 determines whether or not the calculated illuminance exceeds the second threshold value (step S206). For example, as shown in (b) in FIG. 7, calculator 220 is assumed to calculate that the illuminance of background light 320 calculated in step S202 is 2000 lux and that the illuminance of background light 320 calculated in step S205 is 3000 lux. In this case, in step S206, calculator 220 determines that the calculated illuminance exceeds the second threshold value (yes in step S206) so as to select second table information 252 (step S207). On the other hand, when calculator 220 determines that the calculated illuminance does not exceed the second threshold value (no in step S206), calculator 220 keeps first table information 251 selected.

For example, calculator 220 calculates the illuminance of background light 320 again after a predetermined time has elapsed since the performance of step S208 (step S209).

Then, calculator 220 determines whether or not the calculated illuminance drops below the first threshold value (step S210). For example, as shown in (c) in FIG. 7, calculator 220 is assumed to calculate that the illuminance of background light 320 calculated in step S202 is 3000 lux and that the illuminance of background light 320 calculated in step S209 is 1000 lux. In this case, in step S210, calculator 220 determines that the calculated illuminance drops below the first threshold value (yes in step S210) so as to select first table information 251 (step S211). On the other hand, when calculator 220 determines that the calculated illuminance does not drop below the first threshold value (no in step S210), calculator 220 keeps second table information 252 selected.

As described above, calculator 220 changes, from the illuminance of background light 320 and the S/N ratio that are calculated, the table to be used for calculating the limit distance measuring range.

The number of tables included in table information 250 stored in storage 240 is not limited to two and may be greater than or equal to three.

With reference back to FIG. 4, subsequent to step S104, controller 230 calculates, based on the limit distance measuring range calculated by calculator 220, the exposure time (maximum exposure tirne) for which image capturer 110 is exposed (step S105). In step S105, for example, when the limit distance measuring range calculated by calculator 220 in step S104 is a distance up to the sixth section as shown in FIG. 2, the exposure time for measuring a distance to an object located in the sixth section is calculated. A method for calculating the exposure time from the limit distance measuring range is not particularly limited. For example, storage 240 may store an exposure time table indicating a correlation between the limit distance measuring range and the exposure time. For example, controller 230 may calculate, based on the exposure time table, from the limit distance measuring range calculated by calculator 220, the maximum exposure time for which image capturer 110 is exposed.

Then, controller 230 measures the distance to the object by the TOF method (step S106). Specifically, in step S106, controller 203 exposes image capturer 110 while emission light 300 is being emitted from light source 120 until the exposure time calculated in step S105 and while the exposure time is being repeatedly changed until the maximum exposure time calculated based on the limit distance measuring range. In this way, controller 230 measures the distance to the object based on the occurrence count of avalanche multiplication in each of APDs 111.

In step S106, controller 230 may select a predetermined exposure time serving as an exposure time within the maximum exposure time from a plurality of predetermined exposure times stored in storage 240, and expose image capturer 110 for the selected predetermined exposure time serving as the exposure time within the maximum exposure time.

In step S106, controller 230 may calculate, based on the maximum exposure time, the exposure time of image capturer 110, the number of times of exposure of image capturer 110, and the number of times of emission of the light from light source 120, and control image capturer 110 and light source 120 based on the result of the calculation.

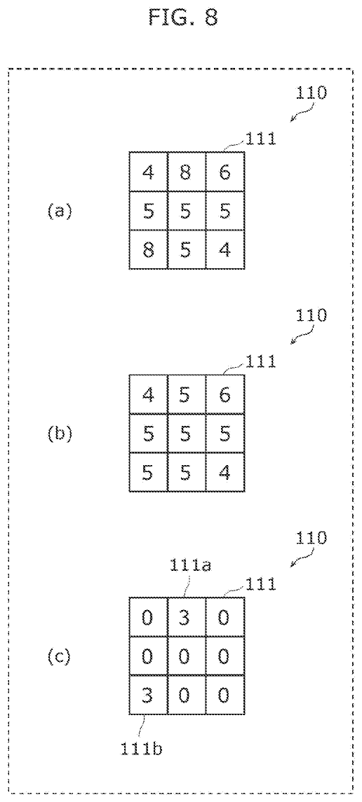

FIG. 8 is a diagrarn showing an example of the occurrence count of avalanche multiplication in each of APDs 111 acquired when distance measuring device 100 according to Embodiment 1 measures the distance to the object. FIGS. 8A to 8C show, as an example, the occurrence count of avalanche multiplication in each of nine APDs 111 when image capturer 110 includes nine APDs 111 arranged in a matrix of 3 rows and 3 columns.

Specifically, (a) in FIG. 8 is a diagram showing an example of the occurrence count of avalanche multiplication in each of APDs 111 when controller 230 causes light source 120 to emit emission light 300. (b) in FIG. 8 is a diagram showing an example of the occurrence count of avalanche multiplication in each of APDs 111 when controller 230 does not cause light source 120 to emit emission light 300, (c) in FIG. 8 is a diagram showing a difference between the occurrence count of avalanche multiplication in each of APDs 111 shown in (a) in FIG. 8 and the occurrence count of avalanche multiplication in each of APDs 111 shown in (b) in FIG. 8.

For example, controller 230 controls image capturer 110 and light source 120, and thus acquirer 210 acquires the occurrence count of avalanche multiplication in each of APDs 111 shown in (a) in FIG. 8 and the occurrence count of avalanche multiplication in each of APDs 111 shown in (b) in FIG. 8. Then, controller 230 calculates the difference shown in (c) in FIG. 8 from the occurrence counts of avalanche multiplication in each of APDs 111 acquired by acquirer 210. Then, controller 230 determines whether or not the difference is greater than or equal to a given occurrence count that is previously determined. When controller 230 determines that the difference is greater than or equal to the given occurrence count that is previously determined, controller 230 determines that the object exists in a given section corresponding to the exposure time so as to measure a distance to the given section as the distance to the object. For example, when the given occurrence count that is previously determined is “2”, controller 230 makes a measurement such that the object exists in directions where APD 111a and APD 111b shown in (c) in FIG. 8 detect light and that the object is located in the given section corresponding to the exposure time.

When calculator 220 calculates the illuminance of background light 320 in step S103, calculator 220 may calculate the average value of an illuminance calculated at a plurality of different times.

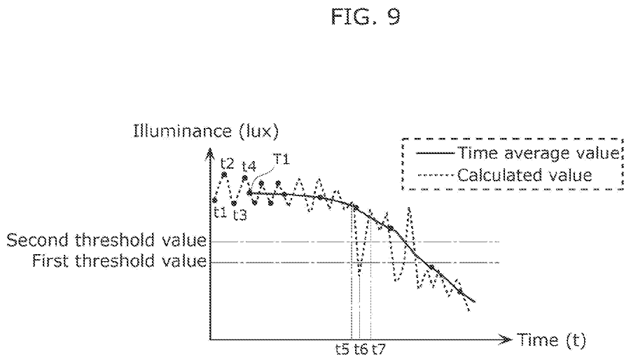

FIG. 9 is a diagram for illustrating a specific example of a method for calculating an illuminance performed by distance measuring device 100 according to Embodiment 1.

For example, controller 230 and acquirer 210 repeat steps S101 and S102 shown in FIG. 4 a multiple number of times. In this way, calculator 220 can calculate, at times, the illuminance of background light 320 a multiple number of times.

For example, as shown in FIG. 9, calculator 220 calculates the illuminance of background light 320 at times t1, t2, t3, and t4 from the occurrence counts of avalanche multiplication obtained as a result of steps S101 and S102 shown in FIG. 4 being repeated four times by controller 230 and acquirer 210. Then, calculator 220 calculates the average value of the illuminance of background light 320 at times t1, t2, t3, and t4 to calculate an illuminance at time T1. Calculator 220 performs, for example, processing subsequent to step S104 shown in FIG. 4 by use of the illuminance at time T1.

As described above, for example, controller 230 performs the exposure processing for exposing image capturer 110 a multiple number of times. In this case, for example, calculator 220 counts the occurrence counts of avalanche multiplication in APDs 111 each time the exposure processing is performed, and calculates the illuminance of background light 320 from the average value of the occurrence counts of avalanche multiplication in APDs 111 counted each time the exposure processing is performed.

For example, it is assumed that as shown in FIG. 9, at time t6, for example, image capturer 110 is blocked and thus the illuminance is sharply lowered from time t5. In this case, for example, since this is a similar change to that shown in (c) in FIG. 7, calculator 220 changes the table information used for calculating the limit distance measuring range from first table information 251 to second table information 252. Furthermore, for example, it is assumed that, at time t7, for example, the state where image capturer 110 is blocked is returned to the original state where image capturer 110 is not blocked and thus the illuminance is sharply increased from time t6. In this case, calculator 220 changes the table information used for calculating the limit distance measuring range from second table information 252 to first table information 251. As described above, depending on timing at which calculator 220 calculates the illuminance, the calculated illuminance may significantly fluctuate, Hence, calculator 220 calculates the average value of the illuminance of background light 320 at a plurality of times, and performs, for example, the processing subsequent to step S104 shown in FIG. 4 by use of the average value of the illuminance.

The number of times controller 230 and acquirer 210 repeat steps S101 and S102 shown in FIG. 4 may be arbitrarily determined.

### [Effects and the Like]

As described above, distance measuring device 100 according to Embodiment 1 is a distance measuring device that measures a distance to an object, and includes: controller 230 that exposes, in an environment where background light 320 is applied to the object, image capturer 110 including a plurality of APDs 111; acquirer 210 that acquires the occurrence count of avalanche multiplication in each of APDs 111; and calculator 220 that acquires, based on the occurrence count of avalanche multiplication in each of APDs 111 acquired by acquirer 210, the limit distance measuring range indicating a distance which can be measured with image capturer 110.

In the configuration as described above, calculator 220 can calculate an appropriate limit distance measuring range according to the illuminance of background light 320. Hence, distance measuring device 100 can measure an appropriate distance according to the illuminance of background light 320. For example, when distance measuring device 100 is installed in a mobile vehicle such as a vehicle, it is possible to appropriately set, according to the illuminance of background light 320 such as sunlight, the maximum value of an intervehicular distance or the like that can be measured.

For example, distance measuring device 100 includes light source 120 and image capturer 110. In this case, for example, by the TOF method, controller 230 exposes image capturer 110 and causes light source 120 to emit the light to calculate the distance to the object based on the occurrence count of avalanche multiplication in each of APDs 111.

In the configuration as described above, controller 230 can measure the appropriate distance based on the appropriate limit distance measuring range. For example, controller 230 appropriately changes the intensity of emission light 300 emitted from light source 120 based on the limit distance measuring range to be able to measure the appropriate distance.

For example, controller 230 calculates the exposure time for which image capturer 110 is exposed based on the limit distance measuring range calculated by calculator 220, exposes image capturer 110y for the calculated exposure time, and calculates the distance to the object based on the occurrence count of avalanche multiplication in each of APDs 111.

In the configuration as described above, controller 230 can calculate the exposure time based on the limit distance measuring range. Hence, controller 230 can measure a more appropriate distance according to the illuminance of background light 320.

For example, controller 230 selects a predetermined exposure time serving as an exposure time within the maximum exposure time from a plurality of different predetermined exposure times, performs the exposure processing for exposing image capturer 110 for the selected predetermined exposure time serving as the exposure time within the maximum exposure time, and calculates the distance to the object based on the occurrence count of avalanche multiplication in each of APDs 111 obtained by performing the exposure processing for each of the predetermined exposure time serving as the exposure time within the maximum exposure time.

In the configuration as described above, for example, even when a plurality of exposure times are previously determined, controller 230 can determine (more specifically can reduce) the number of times the exposure processing is performed based on the maximum exposure time. Hence, since controller 230 does not measure a distance in a region out of the limit distance measuring range, it is possible to reduce the time necessary for measuring the distance, that is, to enhance a frame rate.

For example, controller 230 calculates, based on the maximum exposure time, a plurality of predetermined exposure times, the number of times of exposure, and the number of times of emission of the light from light source 120, repeatedly exposes image capturer 110 for the calculated number of times of exposure for each of the predetermined exposure times serving as the exposure time within the maximum exposure time, and causes light source 120 to emit the light for the calculated number of times of emission.

In the configuration as described above, for example, if the entire exposure time is not changed for one distance measurement, when the exposure processing is not performed for part of the predetermined exposure times that are previously determined, a margin can be produced in the entire exposure time for the one distance measurement for the predetermined exposure time for which the exposure processing is not performed. Hence, for example, the number of times of exposure for each of the predetermined exposure times is increased, and thus the S/N ratio in each distance measuring section can be enhanced. In other words, the accuracy of distance measuring can be enhanced. For example, when light source 120 is pulse-driven, controller 230 may increase the number of pulses based on the maximum exposure time. In this way, for example, as the exposure time is closer to the maximum exposure time, the number of times of emission of the light from light source 120 is increased, with the result that the accuracy of distance measuring in sections close to the limit distance measuring range is enhanced.

For example, calculator 220 calculates the illuminance of background light 320 based on the occurrence count of avalanche multiplication in each of APDs 111, and calculates the limit distance measuring range based on the calculated illuminance of background light 320.

In the configuration as described above, calculator 220 calculates the illuminance of background light 320 based on the occurrence count of avalanche multiplication. Hence, calculator 220 can appropriately calculate the limit distance measuring range based on the illuminance of background light 320.

For example, calculator 220 calculates the illuminance of background light 320 based on the average value of the occurrence counts of avalanche multiplication in at least two or more of APDs 111.

For example, image capturer 110 is assumed to include a large number of APDs 111. In such a case, in order to calculate the average value in all APDs 111, it is necessary to process a large amount of data. Hence, in the configuration as described above, the amount of data used for calculating background light 320 can be reduced.

For example, calculator 220 calculates the illuminance of background light 320 from the average value of the occurrence counts of avalanche multiplication in all APDs 111.

In the configuration as described above, calculator 220 can accurately calculate the illuminance of background light 320.

For example, calculator 220 calculates the limit distance measuring range based on table information 250 indicating the correlation between the illuminance and the limit distance measuring range and the calculated illuminance of background light 320.

In the configuration as described above, it is possible to easily calculate the limit distance measuring range from the occurrence counts of avalanche multiplication in APDs 111. In the configuration as described above, when a plurality of distance measuring devices 100 are manufactured and variations in the accuracy of detection of light by image capturers 110 are produced, table information 250 is appropriately set, and thus it is possible to reduce variations in the measurements of distance measuring devices 100.

For example, table information 250 includes first table information 251 and second table information 252 that is different from first table information 251 in regard to the correlation between the illuminance and the limit distance measuring range. In this case, for example, calculator 220 calculates the S/N ratio that is a ratio of the illuminance of light resulting from reflection of the light emitted from light source 120 off the object to the illuminance of background light 320 from the occurrence counts of avalanche multiplication in APDs 111 when controller 230 causes light source 120 to emit the light and the occurrence counts of avalanche multiplication in APDs 111 when controller 230 does not cause light source 120 to emit the light. Furthermore, for example, calculator 220 selects, based on the calculated S/N ratio, whether to calculate the limit distance measuring range based on first table information 251 or to calculate the limit distance measuring range based on second table information 252.

In the configuration as described above, calculator 220 selects the appropriate table corresponding to the magnitude of the illuminance of background light 320. Hence, in the configuration as described above, calculator 220 can accurately calculate the limit distance measuring range.

For example, at each illuminance between the first threshold value indicating an illuminance and the second threshold value indicating an illuminance higher than the illuminance of the first threshold value, the limit distance measuring range corresponding to the illuminance in first table information 251 is longer than that in second table information 252. For example, when the illuminance of background light 320 drops below the first threshold value, calculator 220 calculates the limit distance measuring range based on first table information 251 whereas when the illuminance of background light 320 exceeds the second threshold value, calculator 220 calculates the limit distance measuring range based on second table information 252.

In the configuration as described above, even when the calculated illuminance is changed for a very short period of time, the changing of the tables to be used many times by calculator 220 is reduced. For example, when calculator 220 changes the tables to be referenced according to whether the illuminance is higher or lower than one threshold value, by a slight fluctuation in the illuminance of background light 320, the tables to be referenced are changed many times. In this configuration, the limit distance measuring range calculated by calculator 220 is repeatedly changed, and thus it is necessary to perform a large amount of processing. Hence, as in the present embodiment, calculator 220 suitably changes the tables to be referenced between first table information 251 and second table information 252, and thus the limit distance measuring range for the illuminance is hysteretically changed. In this way, the changing of the limit distance measuring range calculated by calculator 220 many times for a slight change in the illuminance is reduced.

For example, controller 230 performs the exposure processing for exposing image capturer 110 a multiple number of times. In this case, for example, acquirer 210 acquires the occurrence counts of avalanche multiplication in APDs 111 each time the exposure processing is performed. For example, calculator 220 calculates the illuminance of background light 320 from the average value of the occurrence counts of avalanche multiplication in APDs 111 acquired by acquirer 210 each time the exposure processing is performed.

In the configuration as described above, even when the calculated illuminance is significantly changed for a very short period of time, calculator 220 can select the table with an appropriate illuminance.

The distance measuring method according to Embodiment 1 is a distance measuring method for measuring a distance to an object, and includes: a control step of exposing, in an environment where background light 320 is applied to the object, image capturer 110 including a plurality of APDs 111; an acquisition step of acquiring, from image capturer 110 including APDs 111, the occurrence count of avalanche multiplication in each of APDs 111; and a computation step of calculating, based on the occurrence count of avalanche multiplication in each of APDs 111 acquired in the acquisition step, the limit distance measuring range indicating a distance that can be measured with image capturer 110.

By the method as described above, an appropriate limit distance measuring range can be calculated according to the illuminance of background light 320. Hence, by the method as described above, it is possible to measure an appropriate distance according to the illuminance of background light 320.

The present disclosure may be realized as programs that instruct a computer to perform the steps included in the distance measuring method. The present disclosure may also be realized as a non-transitory computer-readable recording medium, such as a CD-ROM, in which the programs are recorded. The present disclosure may also be realized as information, data, or signals indicating the programs. The programs, the information, the data and the signals may be distributed through a communication network such as the Internet.

### EMBODIMENT 2

A distance measuring device according to Embodiment 2 will be described below. In the description of the distance measuring device according to Embodiment 2, differences from the distance measuring device according to Embodiment 1 will be mainly described, the same configurations as those of the distance measuring device according to Embodiment 1 are identified with the same signs, and descriptions thereof may be partially simplied or omitted.

### [Configuration]

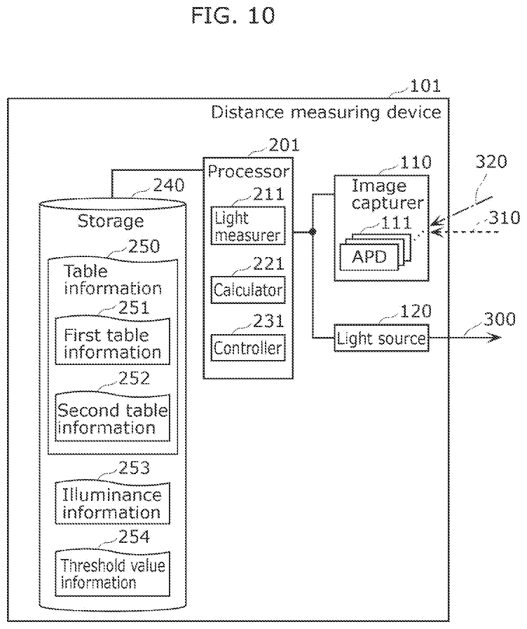

FIG. 10 is a block diagram showing a characteristic functional configuration of distance measuring device 101 according to Embodiment 2.

As with distance measuring device 100, distance measuring device 101 includes image capturer 110 including a plurality of pixels having APDs 111, and is a device that measures a distance to an object. Distance measuring device 101 includes image capturer 110, light source 120, processor 201, and storage 240,

Processor 201 is a processor that controls image capturer 110 and light source 120 to measure the distance to the object (for example, target 400).

Processor 201 is realized, for example, by an input/output port for communication with image capturer 110, light source 120, and the like, a CPU, a control program that is stored in storage 240 or the like and that is executed by the CPU, and the like. Processor 201 is connected to image capturer 110 and light source 120 with control lines or the like to be able to communicate therewith.

Processor 201 functionally includes light measurer 211, calculator 221, and controller 231.

Light measurer 211 measures the illuminance of background light 320 in an environment where background light 320 is applied to the object (for example, target 400 shown in FIG. 1). Light measurer 211 acquires, for example, the occurrence count of avalanche multiplication in each of APDs 111 included in image capturer 110, and calculates the illuminance of background light 320 based on the acquired occurrence count of avalanche multiplication. In other words, light measurer 211 performs processing that is performed by acquirer 210 described previously and part of processing that is performed by calculator 220. As described above, processing that is performed by a specific processor may be performed by another processor.

Light measurer 211 exposes image capturer 110 only with background light 320 without use of light source 120 for emitting light toward the object, acquires the occurrence counts of avalanche multiplication in a plurality of pixels (a plurality of APDs 111) in a state where image capturer 110 is exposed only with background light 320 (that is, without the light being emitted from light source 120), and calculates the illuminance of background light 320 based on illuminance information 253 indicating a correlation between the illuminance of background light 320 and the occurrence counts of avalanche multiplication that are previously converted into data and the occurrence counts of avalanche multiplication in the pixels.

For example, light measurer 211 acquires the occurrence counts of avalanche multiplication in at least two or more of the pixels to calculate the illuminance of the background light based on the average value of the occurrence counts of avalanche multiplication in the two or more of the pixels that are acquired. Alternatively, for example, light measurer 211 acquires the occurrence counts of avalanche multiplication in all the pixels to calculate the illuminance of background light 320 based on the average value of the occurrence counts of avalanche multiplication in all the pixels that are acquired.

In these cases, for example, illuminance information 253 includes a correlation between the illuminance of background light 320 and the average value of the occurrence counts of avalanche multiplication. Light measurer 211 acquires, from image capturer 110, the occurrence counts of avalanche multiplication in the pixels, calculates the average value of the acquired occurrence counts of avalanche multiplication in the pixels, and calculates background light 320 based on the calculated average value and illuminance information 253.

For example, light measurer 211 performs exposure processing for exposing image capturer 110 a multiple number of times, acquires the occurrence counts of avalanche multiplication in the pixels each time the exposure processing is performed, and repeatedly calculates the illuminance of background light 320 based on the average value of the occurrence counts of avalanche multiplication in the pixels acquired each time the exposure processing is performed.

Calculator 221 sets (calculates) a distance measuring range (limit distance measuring range) based on the illuminance of background light 320 measured (calculated) by light measurer 211. As described above, the distance measuring range is a range (the limit value of the distance) of the distance to distance measuring device 101 when distance measuring device 101 measures the distance to the object. Distance measuring device 101 measures the distance to the object that is located within the distance measuring range. Hence, conditions such as the maximum time (maximum exposure time) of the exposure time of image capturer 110 are determined according to the distance measuring range.

For example, calculator 221 sets the distance measuring range based on table information 250 indicating a correlation between the illuminance of background light 320 and the distance measuring range that are previously converted into data. For example, calculator 221 selects, from table information 250, the distance measuring range corresponding to the illuminance of background light 320 measured by light measurer 211, and sets the selected distance measuring range as the distance measuring range (limit distance measuring range) used for measuring the distance to the object.

For example, table information 250 includes first table information 251 and second table information 252.

First table information 251 and second table information 252 each are a table that includes the correlation between the illuminance of background light 320 and the distance measuring range. Second table information 252 is different from first table information 251 in regard to the correlation between the illuminance of background light 320 and the distance measuring range. For example, as described above (see, for example, FIG. 7), at each illuminance between the first threshold value indicating an illuminance and the second threshold value indicating an illuminance higher than the illuminance of the first threshold value, the distance measuring range for the illuminance of background light 320 in first table information 251 is set longer than the distance measuring range for the illuminance of background light 320 in second table information 252.

For example, calculator 221 selects one of first table information 251 and second table information 252 to set the distance measuring range based on the selected table information,

For example, calculator 221 calculates an S/N ratio that is a ratio of the illuminance of light (reflected light 310) resulting from reflection of the light (emission light 300) emitted from light source 120 off the object to the illuminance of background light 320 from the occurrence counts of avalanche multiplication in the pixels when light source 120 is caused to emit the light and the occurrence counts of avalanche multiplication in the pixels when light source 120 is not caused to emit the light, selects one of first table information 251 and second table information 252 based on the calculated S/N ratio, and sets the distance measuring range based on the selected table information.

For example, when as described above (see, for example, FIG. 7), the illuminance of background light 320 drops below the first threshold value, calculator 221 sets the distance measuring range based on first table information 251 whereas when the illuminance of background light 320 exceeds the second threshold value, calculator 221 sets the distance measuring range based on second table information 252.

Information indicating threshold values such as the first threshold value and the second threshold value is previously stored, for example, in storage 240 as threshold value information 254.

For example, calculator 221 selects, based on a change in the illuminance of background light 320 repeatedly calculated by light measurer 211, one of first table information 251 and second table information 252, and sets the distance measuring range based on the selected table information.

In the present embodiment, table information 250 includes two pieces of table information that are first table information 251 and second table information 252. Table information 250 may include three or more pieces of table information that are different from each other in the correlation between the illuminance and the distance measuring range. For example, calculator 221 may select one of the three or more pieces of table information by the method described above and set the distance measuring range based on the selected table information.

Controller 231 sets (determines), based on the distance measuring range set by calculator 221, image capturing conditions of image capturer 110 including the pixels having APDs 111 and emission conditions in which the light is emitted from light source 120. Controller 231 controls image capturer 110 and light source 120 based on the image capturing conditions and the emission conditions that are set so as to measure the distance to the object.

For example, controller 231 sets, as the emission conditions, the intensity, an emission time, and the total number of times of emission of the light from light source 120. Controller 231 sets, as the image capturing conditions, based on the distance measuring range set by calculator 221, a plurality of exposure times and the number of times of exposure (for example, the number of times of exposure for each of the exposure times) for image capturer 110. For example, controller 231 repeatedly exposes image capturer 110 for the set number of times of exposure for each of the exposure times that are calculated to be exposure times within the maximum exposure time which is previously determined according to the set distance measuring range, and causes light source 120 to emit the light for the number of times of emission so as to measure the distance to the object (for example, the distance between the object and distance measuring device 101). Information (exposure time information) indicating the maximum exposure time corresponding to the distance measuring range is previously stored, for example, in storage 240. For example, controller 231 sets a plurality of exposure times that are within (less than or equal to) the maximum exposure time and that are different from each other.

For example, as described previously, controller 231 calculates the first exposure time and the second exposure time such that they are less than or equal to the maximum exposure time, Then, for example, controller 231 controls image capturer 110 such that image capturer 110 is exposed for the first exposure time, and performs control such that light source 120 is caused to emit the light, Controller 231 performs the control described above for the number of times of exposure, Furthermore, controller 231 controls image capturer 110 such that image capturer 110 is exposed for the second exposure time, and performs control such that light source 120 is caused to emit the light. Controller 231 performs the control described above for the number of times of exposure. As described above, controller 231 controls image capturer 110 and light source 120 based on the image capturing conditions and the emission conditions that are set so as to measure the distance to the object.

For example, by the TOF method, controller 231 exposes image capturer 110, causes light source 120 to emit the light, acquires (calculates) the occurrence count of avalanche multiplication in each of APDs 111, and measures the distance to the object based on the occurrence count of avalanche multiplication in each of APDs 111.

Distance measuring device 101 may measure the distance between the object and distance measuring device 101 or may use a previously determined calculation method to measure a distance between the object and an automobile or the like where distance measuring device 101 is arranged.

For example, distance measuring device 101 may include a provider, such as a display or a speaker, that provides the information of the measured distance to a user or the like. For example, distance measuring device 101 measures the distance to the object, and causes the provider to provide information indicating the measured distance.

### [Distance Measuring Method]

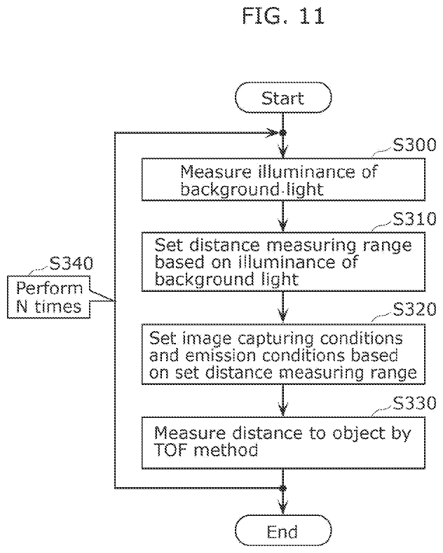

FIG. 11 is a flowchart for illustrating a distance measuring method performed by distance measuring device 101 according to Embodiment 2.

Light measurer 211 first measures the illuminance of background light 320 (step S300).

Then, calculator 221 sets the distance measuring range based on the illuminance of background light 320 measured by light measurer 211 (step S310).

Then, controller 231 sets, based on the distance measuring range set by calculator 221, the image capturing conditions in which image capturer 110 is caused to perform image capturing and the emission conditions in which light source 120 is caused to emit the light (step S320).

Then, controller 231 controls image capturer 110 and light source 120 based on the image capturing conditions and the emission conditions that are set so as to measure the distance to the object, for example, by the TOF method (step S330).

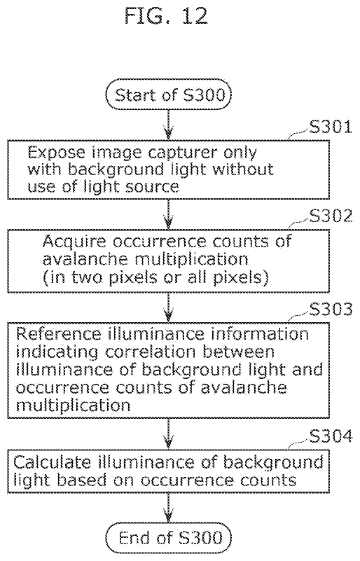

Distance measuring device 101 repeatedly performs the processing from steps S300 to S330 N times (N is a natural number that is arbitrarily determined) (step S340). For example, after distance measuring device 101 repeatedly performs the processing from steps S300 to S330 N times, the processing is completed. FIG. 12 is a flowchart for illustrating details of a light measuring method (step S300) performed by distance measuring device 101 according to Embodiment 2.

Light measurer 211 first exposes image capturer 110 only with background light 320 without use of light source 120 (step S301). In other words, light measurer 211 exposes image capturer 110 in a state where image capturer 110 is exposed only with background light 320 without the light being emitted from light source 120.

Then, light measurer 211 acquires the occurrence counts of avalanche multiplication from image capturer 110 (step S302).

Then, light measurer 211 references illuminance information 253 indicating the correlation between the illuminance of background light 320 and the occurrence counts of avalanche multiplication (step S303).

Then, light measurer 211 calculates, based on illuminance information 253, the illuminance of background light 320 from the occurrence counts of avalanche multiplication (step S304).

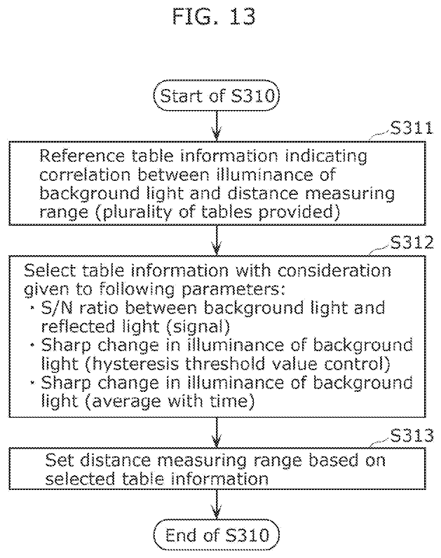

FIG. 13 is a flowchart for illustrating details of the processing (step S310) for setting the distance measuring range performed by distance measuring device 101 according to Embodiment 2.

Calculator 221 first references table information 250 indicating the correlation between the illuminance of background light 320 and the distance measuring range (step S311). When a plurality of pieces of table information are provided (for example, when table information 250 includes a plurality of pieces of table information such as first table information 251 and second table information 252), calculator 221 references the pieces of table information (that is, acquires the pieces of table information from storage 240).

Then, for example, when the pieces of table information are stored in storage 240, calculator 221 selects one of the pieces of table information (step S312).

Here, examples of a method for selecting, by calculator 221, one of the pieces of table information include, as described above, a method for making a selection based on the S/N ratio between the illuminance of background light 320 and the illuminance of reflected light 310, a method based on a sharp change in the illuminance of background light 320 (method using hysteresis threshold value control as described with reference to FIG. 7), a method based on a sharp change in the illuminance of background light 320 (method using the average of a change in the illuminance of background light 320 with time as described with reference to FIG. 9) and the like.

For example, calculator 221 calculates the S/N ratio that is a ratio of the illuminance of light resulting from reflection of the light emitted from light source 120 off the object to the illuminance of background light 320 from the occurrence counts of avalanche multiplication in the pixels when light source 120 is caused to emit the light and the occurrence counts of avalanche multiplication in the pixels when light source 120 is not caused to emit the light, selects one of first table information 251 and second table information 252 based on the calculated S/N ratio, and sets the distance measuring range based on the selected table information. In another method, for example, when the illuminance of background light 320 drops below the first threshold value, calculator 221 sets the distance measuring range based on first table information 251 whereas when the illuminance of background light 320 exceeds the second threshold value, calculator 221 performs the hysteresis threshold value control for setting the distance measuring range based on second table information 252. In yet another method, for example, calculator 221 selects, based on a change in the illuminance of background light 320 repeatedly calculated (for example, the average of a change in the illuminance of background light 320 with time), one of first table information 251 and second table information 252, and sets the distance measuring range based on the selected table information.

Then, calculator 221 sets the distance measuring range based on the selected table information (step S313).

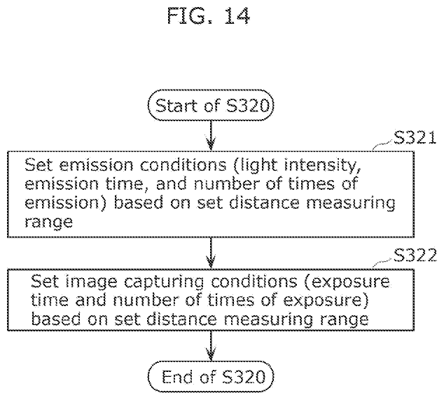

FIG. 14 is a flowchart for illustrating details of the processing (step S320) for setting the image capturing conditions and the emission conditions performed by distance measuring device 101 according to Embodiment 2.

Controller 231 first sets (determines), based on the distance measuring range set by calculator 221, the emission conditions which are details of control of light source 120 (for example, the intensity of the light emitted from light source 120, the emission time at which the light is emitted from light source 120, and the number of times the light is emitted from light source 120 (number of times of emission) (step S321). The emission conditions for the distance measuring range may be arbitrarily set, and is previously stored, for example, in storage 240 as emission condition information.

Then, controller 231 sets (determines), based on the distance measuring range set by calculator 221, the image capturing conditions which are details of control of image capturer 110 (for example, the exposure time indicating the time for which the pixels are exposed and the number of times of exposure indicating the number of times the pixels are exposed) (step S322). The image capturing conditions for the distance measuring range may be arbitrarily set, and is previously stored, for example, in storage 240 as image capturing condition information.

For example, in step S330 shown in FIG. 11, controller 231 controls, based on the image capturing conditions and the emission conditions set in steps S321 and S322, image capturer 110 and light source 120 so as to calculate the distance to the object by the TOF method.

### [Effects and the Like]

As described above, the distance measuring method according to Embodiment 2 includes: measuring, in an environment where background light 320 is applied to the object, the illuminance of background light 320 (step S300); setting the distance measuring range based on the illuminance of background light 320 (step S310); setting, based on the set distance measuring range, the image capturing conditions for image capturer 110 including a plurality of pixels having APDs 111 and the emission conditions in which the light is emitted from light source 120 (step S320); and measuring the distance to the object by controlling image capturer 110 and light source 120 based on the image capturing conditions and the emission conditions that are set (step S330).

In this way, it is possible to set (calculate) the appropriate distance measuring range (limit distance measuring range) according to the illuminance of background light 320. Hence, in the distance measuring method according to Embodiment 2, it is possible to measure, within the appropriate range of the distance corresponding to the illuminance of background light 320, the distance to the object existing within the range. For example, when distance measuring device 100 is installed in a mobile vehicle such as a vehicle, it is possible to appropriately set, according to the illuminance of background light 320 such as sunlight, the maximum value (distance measuring range) of an intervehicular distance or the like that can be measured. Disadvantageously, in the conventional distance measuring device (distance measuring method) that measures a distance with light by the TOF method or the like, a distance that cannot be measured is calculated (measured) depending on the intensity (illuminance) of background light 320. For example, in the conventional distance measuring device, light is emitted in order to measure a distance to an object that is located a distance that cannot be measured depending on the intensity (illuminance) of background light 320. Here, in the conventional distance measuring device, it is likely that since the reflected light of the emitted light cannot be detected, even when the object exists in a position where the distance is measured, an erroneous measurement is made in which the object does not exist and thus the distance cannot be measured. For example, in the conventional distance measuring device, it is likely that when the provider described previously is caused to provide the measured distance to the user or the like, erroneous information indicating that the object does not exist the measured distance is provided. Here, in the distance measuring method according to Embodiment 2, based on the illuminance of background light 320, the limit value (distance measuring range) of the distance for measuring the distance to the object is set. In this way, in the distance measuring method according to Embodiment 2, within the appropriate range of the distance, the distance to the object can be measured. Hence, in the distance measuring method according to Embodiment 2, for example, processing in which a distance that cannot be measured because the illuminance of background light 320 is excessively high is measured can be omitted.

For example, the measuring (step S300) of the illuminance of background light 320 includes: exposing image capturer 110 only with background light 320 without use of light source 120 for emitting the light toward the object (step S301); acquiring the occurrence counts of avalanche multiplication in the pixels in a state where image capturer 110 is exposed only with background light 320 (step S302); and calculating the illuminance of background light 320 based on illuminance information 253 indicating the correlation between the illuminance of background light 320 and the occurrence counts of avalanche multiplication that are previously converted into data and the occurrence counts of avalanche multiplication in the pixels (steps S303 and S304).

In this way, it is possible to accurately calculate the illuminance of background light 320 based on the occurrence counts of avalanche multiplication. It is also possible to measure the illuminance of background light 320 and the distance to the object with a light sensor (image capturer 110) for measuring the distance to the object without use of an illuminance sensor or the like for measuring the illuminance of background light 320.

For example, in the acquiring (step S302) of the occurrence counts of avalanche multiplication in the pixels, the occurrence counts of avalanche multiplication in at least two or more of the pixels are acquired, and in the calculating (steps S303 and S304) of the illuminance of background light 302, the illuminance of background light 302 is calculated based on the average value of the acquired occurrence counts of avalanche multiplication in the two or more of the pixels.

For example, image capturer 110 is assumed to include a large number of pixels (APDs 111). In such a case, in order to acquire the occurrence counts of avalanche multiplication in all APDs 111 and calculate the average value thereof, it is necessary to process a large amount of data. Hence, in this way, the amount of data used for calculating background light 320 can be reduced.

For example, in the acquiring (step S302) of the occurrence counts of avalanche multiplication in the pixels, the occurrence counts of avalanche multiplication in all of the pixels are acquired, and in the calculating (steps S303 and S304) of the illuminance of background light 320, the illuminance of background light 320 is calculated based on the average value of the acquired occurrence counts of avalanche multiplication in all of the pixels.

In this way, the occurrence counts of avalanche multiplication in all APDs 111 are acquired, the average value thereof is calculated, and thus it is possible to accurately calculate background light 320,

For example, in the setting (step S310) of the distance measuring range, the distance measuring range is set based on table information 250 indicating the correlation between the illuminance of background light 320 and the distance measuring range that are previously converted into data (steps S311 to S313).

For example, when a plurality of distance measuring devices 101 that perform the distance measuring method according to Embodiment 2 are manufactured, variations in the accuracy of detection of light by image capturers 110 may be produced. Hence, based on the common information, that is, table information 250, distance measuring devices 101 each calculate the distance measuring range from the measured illuminance. In this way, the distance measuring range corresponding to the accuracy of detection of light by each of image capturers 110 in distance measuring devices 101 is set.

For example, table information 250 includes first table information 251 and second table information 252 that is different from first table information 251 in regard to the correlation between the illuminance of background light 320 and the distance measuring range, and the setting (steps S311 to S313) of the distance measuring range based on table information 250 includes selecting one of first table information 251 and second table information 252 and setting the distance measuring range based on the selected table information.

Depending on the magnitude of the illuminance of background light 320 or the magnitude of a change in the illuminance with time, the appropriate distance measuring range for the illuminance may be different. Hence, for example, the appropriate table information is selected from a plurality of pieces of table information that are different in the correlation between the illuminance and the distance measuring range according to the magnitude of the illuminance of background light 320 or the magnitude of the change in the illuminance with time, and the distance measuring range is set based on the selected table information, with the result that it is possible to measure the distance to the object within a more appropriate range of the distance.

For example, the setting (steps S311 to S313) of the distance measuring range based on table information 250 includes calculating the S/N ratio that is a ratio of the illuminance of light resulting from reflection of the light emitted from light source 120 off the object to the illuminance of background light 320 from the occurrence counts of avalanche multiplication in the pixels when light source 120 is caused to emit the light and the occurrence counts of avalanche multiplication in the pixels when light source 120 is not caused to emit the light, selecting, based on the calculated S/N ratio, one of first table information 251 and second table information 252, and setting the distance measuring range based on the selected table information.

In this way, the appropriate table information is selected from a plurality of pieces of table information according to the magnitude of the illuminance of background light 320 and the magnitude of the illuminance of reflected light 310. Hence, a more appropriate distance measuring range can be set.

For example, at each illuminance between the first threshold value indicating an illuminance and the second threshold value indicating an illuminance higher than the illuminance of the first threshold value, the distance measuring range for the illuminance of background light 320 in first table information 251 is longer than the distance measuring range for the illuminance of background light 320 in the second table information 252, and the setting (steps S311 to S313) of the distance measuring range based on table information 250 includes setting the distance measuring range based on first table information 251 when the illuminance of background light 320 drops below the first threshold value and setting the distance measuring range based on second table information 252 when the illuminance of background light 320 exceeds the second threshold value.

In this way, even when the calculated illuminance of background light 320 (specifically, the magnitude of the illuminance) is changed for a very short period of time, the changing of the table information to be used many times is reduced. For example, when the table information to be referenced is changed according to whether the illuminance of background light 320 is higher or lower than one threshold value, by a slight fluctuation in the illuminance of background light 320, the table information to be referenced is changed many times. In this configuration, the distance measuring range to be set is repeatedly changed, and thus it is necessary to perform a large amount of processing. Hence, as in the present embodiment, the two threshold values are set, and thus the distance measuring range for the illuminance is hysteretically changed between first table information 251 and second table information 252 according to how the illuminance of background light 320 is changed with respect to the two threshold values. In this way, the changing of the set distance measuring range many times for a slight change in the illuminance of background light 320 can be reduced.

For example, the measuring (step S300) of background light 320 includes performing, a multiple number of times, the exposure processing for exposing image capturer 110, acquiring the occurrence counts of avalanche multiplication in the pixels each time the exposure processing is performed, and repeatedly calculating the illuminance of background light 320 based on the average value of the occurrence counts of avalanche multiplication in the pixels acquired each time the exposure processing is performed, and the setting (steps S311 to S313) of the distance measuring range based on table information 250 includes selecting, based on a change in the illuminance of background light 320 calculated repeatedly, one of first table information 251 and second table information 252 and setting the distance measuring range based on the selected table information.

In this way, the appropriate table information is selected according to a change in the magnitude of the illuminance of background light 320 from a plurality of pieces of table information, and the distance measuring range is set based on the selected table information, with the result that it is possible to measure the distance to the object within a more appropriate range of the distance.

For example, the setting (step S320) of the image capturing conditions and the emission conditions includes setting, based on the set distance measuring range, the intensity, the emission time, and the total number of times of emission of the light from light source 120 (step S321) and setting, based on the maximum exposure time in the set distance measuring range, a plurality of exposure times and the number of times of exposure for image capturer 110, and the measuring (step S330) of the distance includes repeatedly exposing image capturer 110 for the set number of times of exposure for each of the exposure times that are calculated to be exposure times within the maximum exposure time which is previously determined according to the set distance measuring range and causing light source 120 emit the light for the set number of times of emission to measure the distance to the object.

In this way, the details of the control of image capturer 110 and light source 120 are determined based on the distance measuring range, and thus it is possible to accurately measure the distance to the object existing within the appropriate range of the distance.

Distance measuring device 101 according to Embodiment 2 includes: light measurer 211 that measures, in an environment where background light 320 is applied to the object, the illuminance of background light 320; calculator 221 that sets the distance measuring range based on the illuminance of background light 320; and controller 231 that sets, based on the distance measuring range set by calculator 221, the image capturing conditions for image capturer 110 including a plurality of pixels having APDs 111 and the emission conditions in which the light is emitted from light source 120 and that controls image capturer 110 and light source 120 based on the image capturing conditions and the emission conditions which are set so as to measure the distance to the object.

In this way, calculator 221 can set (calculate) the appropriate distance measuring range (limit distance measuring range) according to the illuminance of background light 320. Hence, distance measuring device 101 can measure, within the appropriate range of the distance corresponding to the illuminance of background light 320, the distance to the object existing within the range. For example, when distance measuring device 101 is installed in a mobile vehicle such as a vehicle, it is possible to appropriately set, according to the illuminance of background light 320 such as sunlight, the maximum value (distance measuring range) of an intervehicular distance or the like that can be measured. Disadvantageously, in the conventional distance measuring device that measures a distance with light by the TOF method or the like, a distance that cannot be measured is calculated (measured) depending on the intensity (illuminance) of background light 320. For example, in the conventional distance measuring device, light is emitted in order to measure a distance to an object that is located a distance that cannot be measured depending on the intensity (illuminance) of background light 320. Here, in the conventional distance measuring device, it is likely that since the reflected light of the emitted light cannot be detected, even when the object exists in a position where the distance is measured, an erroneous measurement is made in which the object does not exist and thus the distance cannot be measured, For example, in the conventional distance measuring device, it is likely that when the provider described previously is caused to provide the measured distance to the user or the like, erroneous information indicating that the object does not exist the measured distance is provided. Here, based on the illuminance of background light 320, distance measuring device 101 sets the limit value (distance measuring range) of the distance for measuring the distance to the object. In this way, distance measuring device 101 can measure, within the appropriate range of the distance, the distance to the object. Hence, in distance measuring device 101, for example, processing in which a distance that cannot be measured because the illuminance of background light 320 is excessively high is measured can be omitted.

For example, distance measuring device 101 includes light source 120 and image capturer 110. For example, by the TOF method, controller 231 exposes image capturer 110 and causes light source 120 to emit the light so as to measure the distance to the object based on the occurrence counts of avalanche multiplication in APDs 111.

In this way, controller 231 can measure, based on the appropriate distance measuring range, the distance to the object existing the appropriate distance. For example, controller 231 appropriately changes the intensity of the light emitted from light source 120 based on the distance measuring range to be able to measure the distance to the object within the appropriate range of the distance.

The present disclosure may be realized as programs that instruct a computer to perform the steps included in the distance measuring method, The present disclosure may also be realized as a non-transitory computer-readable recording medium, such as a CD-ROM, in which the programs are recorded. The present disclosure may also be realized as information, data, or signals indicating the programs. The programs, the information, the data and the signals may be distributed through a communication network such as the Internet.

### OTHER EMBODIMENTS

Although the distance measuring devices according to the embodiments and the like have been described above based on the embodiments, the present disclosure is not limited to the embodiments. Embodiments obtained by causing various types of variations conceived by those skilled in the art on the present embodiments or embodiments formed by combining constituent elements in different embodiments may be included in the scope of one or a plurality of aspects without departing from the spirit of the present disclosure.

For example, in the embodiments described above, processing performed by a specific processor such as the calculator or the controller may be performed by another processor. The order in which a plurality of types of processing are performed may be changed or a plurality of types of processing may be performed simultaneously. The allocation of the constituent elements included in the distance measuring device to a plurality of devices is an example. For example, constituent elements included in one device may be included in another device. For example, part of the constituent elements included in the processor may be included in the image capturer. The distance measuring device may be realized as a single device.

For example, processing described in the embodiments described above may be realized by centralized processing with a single device (system) or may be realized by distributed processing with a plurality of devices. One or a plurality of processors may execute the programs described above. In other words, centralized processing may be performed or distributed processing may be performed.

In the embodiments described above, all or part of the constituent elements of the processor may be formed by dedicated hardware or may be realized by executing software programs suitable for the constituent elements. A program executor such as a central processing unit (CPU) or a processor may read and execute software programs recorded in a recording medium such as a hard disk drive (HDD) or a semiconductor memory so as to realize the constituent elements.

For example, constituent elements such as the processor may be formed with one or a plurality of electronic circuits. One or a plurality of electronic circuits each may be a general-purpose circuit or a dedicated circuit. Examples of one or a plurality of electronic circuits may include a semiconductor device, an integrated circuit (IC), a large scale integration (LSI) circuit and the like. The IC or the LSI circuit may be integrated into one chip or may be integrated into a plurality of chips. Although here, the IC or the LSI circuit is mentioned, what is mentioned is changed according to the degree of integration, and it may be a system LSI circuit, a very large scale integration (VLSI) circuit or an ultra large scale integration (ULSI) circuit. A field programmable gate array (FPGA) that is programmed after manufacturing of a LSI circuit can also be used for the same purpose.

A general or specific aspect of the present disclosure may be realized by a system, a device, a method, an integrated circuit, or a computer program. The general or specific aspect may also be realized by a non-transitory computer-readable recording medium, such as an optical disc, a hard disk drive (HDD), or a semiconductor memory, in which the computer program is recorded. The general or specific aspect may also be realized by any combination of a system, a device, a method, an integrated circuit, a computer program, and a recording medium.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The distance measuring device according to the present disclosure is applicable to distance measuring devices that use APDs to measure a distance to an object.

1. A distance measuring method, comprising:
measuring, in an environment where background light is applied to an object, an illuminance of the background light;
setting a distance measuring range based on the illuminance of the background light;
setting, based on the distance measuring range set, an image capturing condition for an image capturer including a plurality of pixels each including an avalanche photo diode (APD) and an emission condition in which light is emitted from a light source; and
measuring a distance to the object by controlling the image capturer and the light source based on the image capturing condition and the emission condition that are set.

2. The distance measuring method according to claim 1,
wherein the measuring of the illuminance of the background light includes:
exposing the image capturer only with the background light without use of the light source that emits the light toward the object;
acquiring occurrence counts of avalanche multiplication in the plurality of pixels in a state where the image capturer is exposed only with the background light; and
calculating the illuminance of the background light based on illuminance information indicating a correlation between the illuminance of the background light and occurrence counts of avalanche multiplication that are previously converted into data and the occurrence counts of avalanche multiplication in the plurality of pixels.

3. The distance measuring method according to claim 2,
wherein in the acquiring of the occurrence counts of avalanche multiplication in the plurality of pixels, occurrence counts of avalanche multiplication in at least two or more of the plurality of pixels are acquired, and
in the calculating of the illuminance of the background light, the illuminance of the background light is calculated based on an average value of the occurrence counts of avalanche multiplication acquired in the at least two or more of the plurality of pixels.

4. The distance measuring method according to claim 2,
wherein in the acquiring of the occurrence counts of avalanche multiplication in the plurality of pixels, occurrence counts of avalanche multiplication in all of the plurality of pixels are acquired, and
in the calculating of the illuminance of the background light, the illuminance of the background light is calculated based on an average value of the occurrence counts of avalanche multiplication acquired in the all of the plurality of pixels.

5. The distance measuring method according to claim 1,
wherein in the setting of the distance measuring range, the distance measuring range is set based on table information indicating a correlation between the illuminance of the background light and the distance measuring range that are previously converted into data.

6. The distance measuring method according to claim 5,
wherein the table information includes first table information and second table information that is different from the first table information in regard to the correlation between the illuminance of the background light and the distance measuring range, and
the setting of the distance measuring range based on the table information includes:
selecting one of the first table information and the second table information; and
setting the distance measuring range based on the one of the first table information and the second table information selected.

7. The distance measuring method according to claim 6,
wherein the setting of the distance measuring range based on the table information includes:
calculating an S/N ratio that is a ratio of an illuminance of light resulting from reflection of the light emitted from the light source off the object to the illuminance of the background light from occurrence counts of avalanche multiplication in the plurality of pixels when the light source is caused to emit the light and occurrence counts of avalanche multiplication in the plurality of pixels when the light source is not caused to emit the light;
selecting, based on the S/N ratio calculated, one of the first table information and the second table information; and
setting the distance measuring range based on the one of the first table information and the second table information selected.

8. The distance measuring method according to claim 6,
wherein, at each illuminance between a first threshold value indicating an illuminance and a second threshold value indicating an illuminance higher than the illuminance of the first threshold value, the distance measuring range for the illuminance of the background light in the first table information is longer than the distance measuring range for the illuminance of the background light in the second table information, and
the setting of the distance measuring range based on the table information includes:
setting the distance measuring range based on the first table information when the illuminance of the background light drops below the first threshold value; and
setting the distance measuring range based on the second table information when the illuminance of the background light exceeds the second threshold value.

9. The distance measuring method according to claim 6, wherein the measuring of the illuminance of the background light includes:
performing, a multiple number of times, exposure processing for exposing the image capturer;
acquiring occurrence counts of avalanche multiplication in the plurality of pixels each time the exposure processing is performed; and
repeatedly calculating the illuminance of the background light based on an average value of the occurrence counts of avalanche multiplication in the plurality of pixels acquired each time the exposure processing is performed, and
the setting of the distance measuring range based on the table information includes:
selecting, based on a change in the illuminance of the background light calculated repeatedly, one of the first table information and the second table information; and
setting the distance measuring range based on the one of the first table information and the second table information selected.

10. The distance measuring method according to claim 1,
wherein the setting of the image capturing condition and the emission condition includes:
setting, based on the distance measuring range set, as the emission condition, an intensity, an emission time, and a total number of times of emission of the light from the light source; and
setting, based on the distance measuring range set, as the image capturing condition, a plurality of exposure times and a total number of times of exposure; and
the measuring of the distance includes:
repeatedly exposing the image capturer for the total number of times of exposure for each of the plurality of exposure times that are calculated to be exposure times within a maximum exposure time which is previously determined according to the distance measuring range set; and
causing the light source to emit the light for the total number of times of emission to measure the distance to the object.

11. A distance measuring device, comprising:
a light measurer that measures, in an environment where background light is applied to an object, an illuminance of the background light;
a calculator that sets a distance measuring range based on the illuminance of the background light; and
a controller that sets, based on the distance measuring range set, an image capturing condition for an image capturer including a plurality of pixels each including an avalanche photo diode (APD) and an emission condition in which light is emitted from a light source and that controls the image capturer and the light source based on the image capturing condition and the emission condition which are set so as to measure a distance to the object.

12. The distance measuring device according to claim 11, comprising:
the light source; and
the image capturer,
wherein, by a time of flight (TOF) method, the controller exposes the image capturer and causes the light source to emit the light so as to measure the distance to the object based on occurrence counts of avalanche multiplication in the APBs.

13. A non-transitory computer-readable recording medium, the recording medium having a program recorded thereon for causing the computer to execute the distance measuring method according to claim 1.
